(19) United States
(12) Patent Application Publication
(10) Pub. No.: US 2002/0173166 A1
(43) Pub. Date: Nov. 21, 2002

(54) Method and apparatus to quickly increase the concentration of gas in a process chamber to a very high level

(76) Inventors: Kurt Christenson, Minnetonka, MN (US); Steven L. Nelson, Minnetonka, MN (US)

Correspondence Address: VIDAS, ARRETT & STEINKRAUS, P.A., 6109 BLUE CIRCLE DRIVE, SUITE 2000, MINNETONKA, MN, 55343-9185, US

(21) Appl. No.: 09/681,463

(22) Filed: Apr. 11, 2001

(51) Int. Cl. H01L 21/31; H01L 21/469; H01L 21/26; H01L 21/324; H01L 21/42

(52) U.S. Cl. 438/775; 438/776

(57) ABSTRACT

An in-process microelectronic device may be treated by providing a process chamber with an in-process microelectronic device therein, providing an ozone generator and an ozone storage reservoir, the ozone storage reservoir in fluid communication with the ozone generator and the process chamber, generating ozone with the ozone generator for a first period of time and delivering the ozone to the ozone storage reservoir; and subsequently providing ozone from the ozone storage reservoir and the generator to the process chamber during a second period of time different from the first period of time and exposing the in-process microelectronic device thereto.

### BACKGROUND OF INVENTION

In the area of semiconductor processing, ozone is used as a process chemical in the manufacture of microelectronic devices. For example, ozone may be used in a variety of dry techniques and wet techniques to remove unwanted organic material from semiconductor substrates. It is also used to form layers or features on in-process devices.

Dry techniques typically involve the use of ozone gas and optionally ultraviolet light to remove unwanted materials from a semiconductor substrate. The use of ozone gas in a dry process has been disclosed in U.S. Pat. No. 5,709,754.

Wet techniques involve the use of ozone and a liquid such as water. The use of aqueous ozone in a wet process has been disclosed in U.S. Pat. No. 6,080,531. In accordance with U.S. Pat. No. 6,080,531, a treating solution of ozone and optionally bicarbonate or other suitable radical scavenger is used to treat a substrate for use in an electronic device. The method is particularly well suited to photoresist removal where certain metals such as aluminum, copper and oxides thereof are present on the surface of the substrate. The method is also well suited to the removal of organic materials as well. During a typical treatment process, the electronic devices or substrates are subjected to a sequence of stripping, rinsing and drying. A process such as that disclosed in U.S. Pat. No. 6,080,531 may suitably be carried out in a spray processor such as the Mercury MP® Spray Processor, FSI International, Chaska, Minn. or in the ZETA™ surface conditioning system, FSI International, Chaska, Minn.

Ozone may also be used as an assist gas in the chemical vapor deposition of silicon oxide, for forming field oxides on silicon substrates, for making thin gate oxides and in TEOSplanarization processes. More generally, ozone may be used as a strong oxidant in the treatment of an in-process microelectronics device.

The above-mentioned processes, as well as many other ozone-based processes for the treatment of semiconductor substrates may involve the intermittent use of ozone or require time varying amounts of ozone. In an ozone-based photoresist stripping process, for example, the actual strip portion of the process when ozone is heavily utilized takes only a fraction, e.g., approximately one half, of the total process time. During the remainder of the process, however, ozone capacity is underutilized.

Ozone is typically generated by exposing oxygen to high voltage electricity in an ozone generator. This generates a mixture of ozone and oxygen in which the ozone content is from about 1% to about 15% by volume. Currently, it is not practical to generate an ozone/oxygen gas mixture with a higher concentration of ozone gas. Thus, where large amounts of ozone are required, the flow rate of oxygen into the generator may be increased resulting in the output of increased amounts of ozone. By increasing the flow rate through the generator, however, the residence time of the oxygen in the generator is reduced, thereby decreasing the concentration of the ozone. Where lower absolute amounts of ozone and higher ozone concentrations are required, the flow rate of oxygen into the generator may be decreased, thereby increasing the residence time of the oxygen in the generator.

Advances have been made in the production of ozone in general and in the ozonation of liquids such as water in particular. To that end, U.S. Pat. No. 5,989,407 discloses an ozone generation and delivery system. U.S. Pat. No. 5,971,368 discloses a system for increasing the quantity of dissolved gasses such as ozone in a liquid such as water. Nevertheless, there remains a need for innovative methods for ozone production and supply.

Advances have also been made in the handling and storage of ozone. U.S. Pat. No. 5,888,271, for example, discloses a system for storing ozone. The system includes an ozone generator, an adsorption/desorption tower including silica gel adsorbent for adsorbing ozone from ozonized oxygen gas and desorbing apparatus for desorbing ozone from the adsorbent.

Unfortunately, in processes employing ozone in which the demand for ozone is intermittent or otherwise variable over time, the ozone capacity is not used efficiently. Ozone generators cannot simply be turned on and off during most processes without deleterious effects because of the time required for ozone generators to reach steady state. The additional time that would be required may slow process time and hence reduce throughput dramatically. It is thus advantageous to run the ozone generator continuously even when ozone is not needed at the point of use. Consequentially, during periods of off-demand, ozone is wasted. It would be desirable to use the ozone capacity of the generator more efficiently in processes in which the demand for ozone is intermittent and more ozone is generated than is used.

There remains a need for novel methods of using ozone gas more efficiently in the processing of in-process microelectronics devices and for devices which accomplish the same.

All US patents and applications all other published documents mentioned anywhere in this application are incorporated herein by reference in their entirety.

Without limiting the scope of the invention in any way, the invention is briefly summarized in some of its aspects below. Additional details of the invention and/or additional embodiments of the invention may be found in the Detailed Description of the Invention below.

A brief abstract of the technical disclosure in the specification is provided as well only for the purposes of complying with 37 C.F.R. 1.72. The abstract is not intended to be used for interpreting the scope of the claims.

### SUMMARY OF INVENTION

The invention is directed in one aspect to methods of efficiently using ozone in the treatment of in-process microelectronics devices and systems for accomplishing the same. Using a high efficiency method disclosed herein, processes employing ozone may be carried out using smaller ozone generators than would otherwise be possible while meeting the ozone requirement of the process. Alternatively, for a given size generator, a higher ozone demand may be serviced.

The inventive methods and systems in one or more embodiments are based, in part, on storing the ozone gas output of an ozone gas generator in a storage reservoir when there is reduced or no demand for ozone at the point(s) of use and then using stored ozone gas, optionally in combination with fresh ozone gas, to meet the demand for ozone at the point of use. By providing ozone from the storage reservoir to a process chamber at a flow rate of Qᵣ and from the ozone generator to the process chamber at a flow rate of Q_{g}, a total ozone flow of Qₚ equal to the sum of Q_{g} and Qᵣ may be provided to the process chamber. This flow rate exceeds the flow rate which may be generated by the ozone generator alone. Also, the ozone stored in the reservoir gets used productively, increasing use efficiency dramatically.

In one aspect, the invention is directed to a method of treating an in-process microelectronic device comprising the steps of providing a process chamber with an in-process microelectronic device therein, providing an ozone generator and an ozone storage reservoir, the ozone storage reservoir in fluid communication with the ozone generator and the process chamber, generating ozone with the ozone generator for a first period of time and delivering the ozone to the ozone storage reservoir and subsequently providing ozone from the ozone storage reservoir and optionally the generator to the process chamber during a second period of time different from the first period of time and exposing the in-process microelectronic device thereto.

In another aspect, the invention is directed to an improvement in a method of treating at least one in-process microelectronic device in a process chamber where the method comprises an ozone supply step in which ozone is supplied to the process chamber in the presence of the in-process microelectronic device and at least one step in which the in-process microelectronic device is processed without delivery of ozone to the process chamber. The improvement comprises the steps providing an ozone generator and an ozone storage reservoir, the ozone storage reservoir in fluid communication with the ozone generator and the process chamber, generating ozone with the ozone generator during the step or steps in which the in-process microelectronic device is processed without delivery of ozone to the process chamber, and delivering the generated ozone to the ozone storage reservoir and subsequently delivering ozone from the ozone storage reservoir to the process chamber during the ozone supply step to treat the in-process microelectronic device. The flow of ozone from the ozone storage reservoir to the process chamber may optionally be supplemented by ozone from the ozone generator.

In another aspect, the invention is directed to a method of treating at least one substrate with a temporally varying amount of ozone, the substrate comprising an element selected from the group consisting of Si, Ge and Ga. More desirably, the substrate comprises Si, SiO₂, Ge, and/or GaAs, The method comprises the steps of providing a process chamber having a substrate therein, the substrate comprising an element selected from the group consisting of Si, Ge and Ga, and desirably, a material selected from the group consisting of Si, Ge, SiO₂ and GaAs, providing an ozone generator capable of generating an ozone output of Q_{g} liters per minute, providing a storage reservoir for storing ozone therein, generating Q_{g} liters per minute of ozone during a first time period in which a flow Qₚ liters per minute less than Q_{g} liters per minute of ozone is required, storing Q_{g}-Qₚ liters per minute of ozone in the storage reservoir during the first time period and, subsequent to storing the ozone, delivering a flow of Qᵣ liters per minute of stored ozone to the process chamber to treat the substrate. The flow of ozone from the ozone storage reservoir to the process chamber may optionally be supplemented by ozone from the ozone generator.

In another aspect, the invention is directed to a processor for treating an in-process microelectronic device. The processor comprises an ozone generator having a first output of ozone, an ozone storage reservoir comprising ozone therein and a process chamber for holding the in-process microelectronic device. A first line connects the ozone generator and the storage reservoir and a second line connects the storage reservoir and the process chamber. The second line includes a controllable valve controlling flow of ozone between the storage reservoir and the process chamber whereby ozone may be delivered from the storage chamber to the process chamber at selected times. The processor further comprises a controller in communication with the controllable valve. The controller includes a computing unit having a control program installed therein and is operable to control the controllable valve according to the control program so as to allow for storage of ozone in the storage reservoir at predetermined times and to provide ozone to the process chamber from the storage reservoir at predetermined times. The flow of ozone from the ozone storage reservoir to the process chamber may optionally be supplemented by ozone from the ozone generator.

In yet another aspect, the invention is directed to an improved processor for treating an in-process microelectronic device with ozone, comprising an ozone generator having an output of ozone, a process chamber for holding the in-process microelectronic device and a supply line connecting the ozone generator and the process chamber. The improvement comprises providing the supply line with an ozone storage reservoir, a controllable valve between the storage reservoir and the process chamber and a controller in communication with the controllable valve. The controller is programmed to close the valve at predetermined times to allow for storage of ozone in the storage reservoir and to open the valve at predetermined times to allow stored ozone into the process chamber. The flow of ozone from the ozone storage reservoir to the process chamber may optionally be supplemented by ozone from the ozone generator.

In yet another aspect, the invention is directed to a method of treating an in-process microelectronic device comprising the steps of providing a first flow of gas comprising ozone, storing at least a portion of the first flow in a gaseous state in a storage reservoir, withdrawing a second flow of gas from the reservoir, combining the second flow and at least a portion of the first flow to provide a combined gas flow and incorporating the combined gas flow into a treatment of the in-process microelectronic device.

In yet another embodiment, the invention is directed to a method of using a supply of ozone gas to carry out a process having a temporally variable demand for ozone. In accordance with the method, a steady state supply of a gas comprising ozone is provided. During a period of a relatively low demand for ozone by the process, an amount of ozone gas is stored and during a period of a relatively high demand for ozone by the process, the process is carried out using the stored ozone and at least a portion of the steady state supply of ozone. The method may include other steps as well.

Additional details and/or embodiments of the invention are discussed below.

### BRIEF DESCRIPTION OF DRAWINGS

FIG. 1 is a diagram of one embodiment of an inventive ozone storage and delivery system.

FIG. 2 is a diagram of another embodiment of an inventive ozone storage and delivery system.

FIG. 3 is a schematic diagram of one mode of operation of the inventive ozone storage system in accordance with the invention.

FIG. 4 is a schematic diagram of another mode of operation of the inventive ozone storage system in accordance with the invention.

FIG. 5 is a schematic diagram of another mode of operation of the inventive ozone storage system in accordance with the invention.

FIG. 6 is a schematic diagram of another mode of operation of the inventive ozone storage system in accordance with the invention.

FIG. 7 is a diagram of another embodiment of an inventive ozone storage and delivery system.

FIG. 8 depicts the concentration of ozone in a process chamber as a function of time for ozone delivered in accordance with an embodiment of the invention and for ozone delivered directly from an ozone generator.

### DETAILED DESCRIPTION

While this invention may be embodied in many different forms, there are shown in the drawings and described in detail herein specific embodiments of the invention. The present disclosure is an exemplification of the principles of the invention and is not intended to limit the invention to the particular embodiments illustrated.

For the purposes of this disclosure, unless otherwise indicated, identical reference numerals used in different figures refer to the same component.

The present invention in one of its aspects provides a novel method of utilizing ozone more efficiently in processes for treating one or more in-process microelectronic devices with ozone where the demand for ozone at the point of use is intermittent or otherwise variable. For the purposes of this disclosure, the term “in-process microelectronic device” shall refer to semiconductor wafer substrates and other substrates including semiconductor materials such as Si, Ge or GaAs, micromachines, flat panel displays, magnetic and optical storage devices, thin film magnetic or GMR (giant magneto resistive) heads, integrated circuits, any other microelectronics device, and the like while being fabricated.

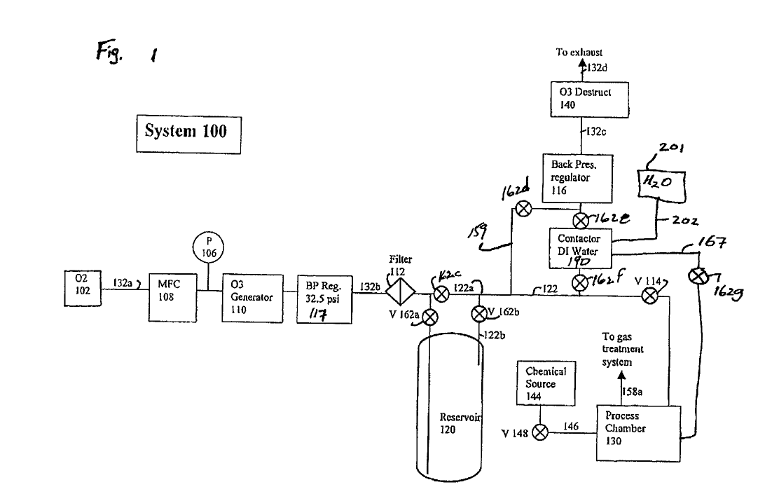

Referring now to FIG. 1, an embodiment of the inventive ozone storage and delivery system is shown generally at 100.

System 100 comprises ozone generator 110, ozone storage reservoir 120, process chamber 130 and ozone destructor 140. A gas feed comprising oxygen is supplied to ozone generator from oxygen source 102 via supply line 132a. The pressure of the oxygen gas delivered to ozone generator 110 is monitored by pressure gauge 106 and the flow of oxygen is controlled by flow control device 108, desirably a mass flow controller.

Ozone generator 110 outputs a mixture including ozone gas and oxygen gas. Other optional gaseous constituents may also be present or added to the gas mixture upstream or downstream from the generator. Desirably, ozone generator 110 is operated continuously at steady state. When operated at steady state, the generator outputs ozone gas at a flow rate of Q_{g} as part of the gaseous mixture including ozone and oxygen. The gaseous mixture is desirably filtered via filter 112 to remove any particles or other contaminants from the gaseous mixture. Filter 112 may be provided directly at the output port of the ozone generator (not shown) or may be provided downstream of the output port as shown in FIG. 1. In the latter case, ozonated gas is directed to filter 112 via supply line 132b. An optional back pressure regulator 117 may also be provided. Any suitable back pressure regulator may be used. One such suitable back pressure regulator is the Tescom 44-2361-24 back pressure regulator.

Storage reservoir 120 is provided downstream from ozone generator 110. Optionally, valve 162a is provided to control the flow of ozone gas into the storage reservoir. Valves 162a,b may be closed to isolate the storage chamber from the ozone generator or valve 162a may be fully or partially opened, as desired, to allow for the flow of ozone from the generator into the storage reservoir.

Storage reservoir 120 is in communication, via line 159, with ozone destructor 140 through which ozone is converted to oxygen and exhausted via line 132d. A back-pressure controlled valve 116 is provided between the storage reservoir and ozone destructor 140 to maintain, if desired, a desired pressure in storage reservoir 120.

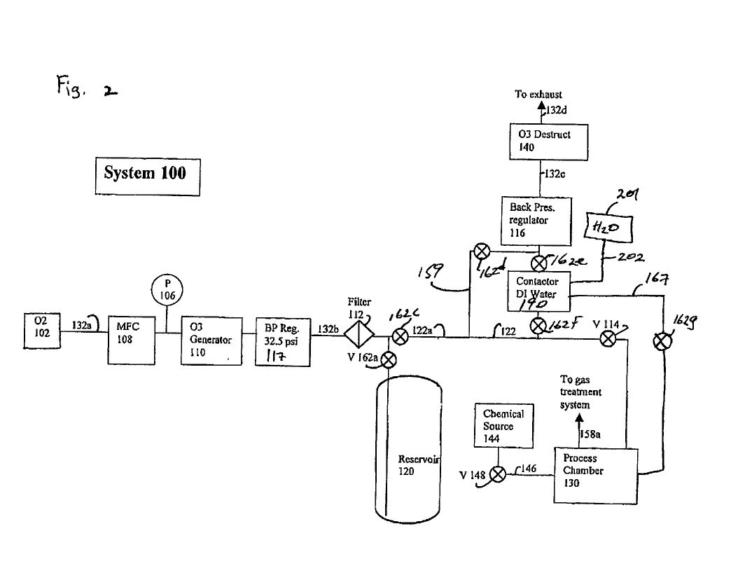

Ozone from generator 110 flows to process chamber 130 via one or more lines. The line(s) may be provided in several different locations. In one embodiment, as shown in FIG. 1, a single line 122a, optionally in fluid communication with storage reservoir 120, extends between ozone generator 110 and line 122 which is in fluid communication with process chamber 130. Line 122 may carry all or a portion of the gas directly to process chamber 130 by-passing reservoir 120. Second line 122b extends between storage reservoir 120 and line 122 to carry gas from storage reservoir 120 to process chamber 130. It is understood, however, that only a single line between storage reservoir 120 and process chamber 130 is necessary, as shown in FIG. 2 although multiple lines may be provided.

The ozone may optionally be dissolved in water or any other appropriate liquid via contactor 190 prior to delivery to process chamber 130. Contactor 190 may be supplied with water, desirably deionized water, from water source 201 via line 202. Flow of ozone to contactor 190 may be controlled by valves 162d, 162e and 162f. Flow of ozonated liquid from contactor 190 to process chamber 130 via line 167 may be controlled by valve 162g. Any suitable contactor may be used. An example of a suitable contactor is the Gore Disso3lve Ozonation Module.

Process chamber 130 may be exhausted to atmosphere or to a suitable gas treatment system via line 158a.

Storage reservoir 120 is desirably pressurized to allow storage of a larger supply of ozone gas. Where storage reservoir 120 is pressurized and process chamber 130 is not pressurized, the pressure difference will drive the flow of ozone gas from storage reservoir 120 to process chamber 130 via line 122b, as shown in FIG. 1 or line 122a as shown in FIG. 2 and line 122.

It is also within the scope of the invention, regardless of whether storage reservoir 120 is or is not pressurized, to provide a device for moving ozone gas from storage reservoir 120 to process chamber 130. Suitable devices for moving ozone gas include a piston, an inflatable bladder or other suitable pump or transport device.

System 100 may optionally comprise one or more other sources of chemical 144 in communication with process chamber 130 via line 146 and optional valve 148. Line 146 may enter process chamber 130 directly or may be coupled into line 122. Source 144 may comprise an acid or radical scavenger for processes in which ozone is used to strip photoresist or other cleaning processes involving HF, HCl NH₄OH or other chemicals. Other illustrative chemicals include various silicon containing compounds such as tetraorthosilicate where ozone is used as an assist gas in chemical vapor deposition processes.

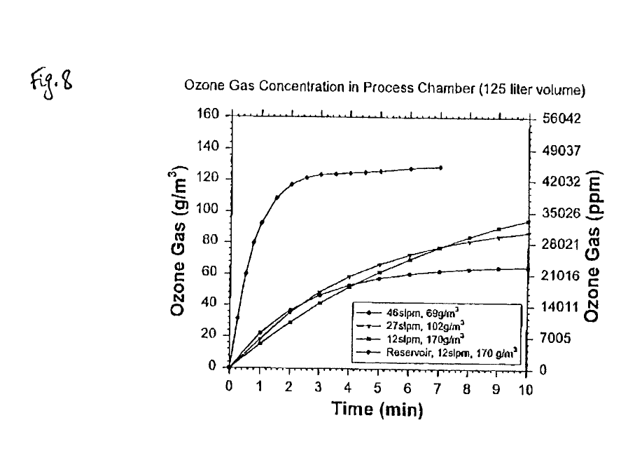

System 100 may be operated in a number of different modes including a mode in which the reservoir is charged, a mode in which gas goes from generator 110 to both reservoir 120 and process chamber 130, a mode in which gas goes from generator 110 to process chamber 130 or multiple process chambers as shown in FIG. 7 and several other process chamber charging modes. The invention also contemplates providing multiple ozone generators and/or storage reservoirs in conjunction with one or more process chambers. For example, two or more ozone generators may supply a reservoir which in turn supplies one and desirably a plurality of processing chambers. In one or more modes of operation, ozone is supplied to the storage reservoir and process chamber(s) simultaneously.

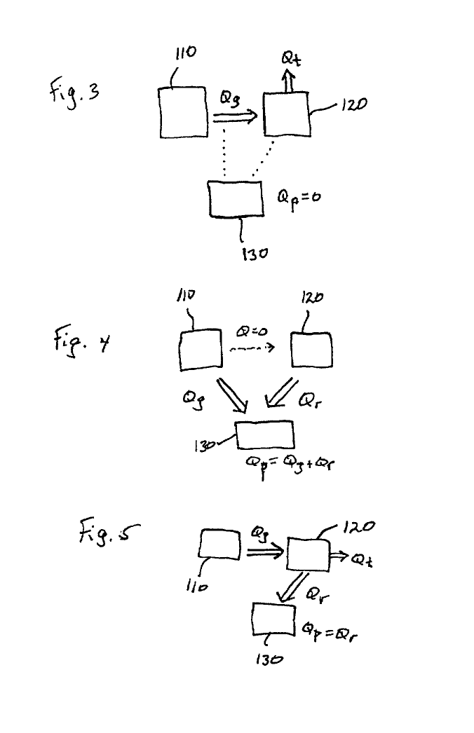

When operated in a desired reservoir charging mode, as shown schematically in FIG. 3 and with reference to FIG. 1, on/off valve 114 is closed to prevent flow of ozone gas into process chamber 130 and valve 162a, when present, is opened. Pressurized, filtered ozone gas flows into storage reservoir 120 via supply line 132b, desirably at the steady state flow rate of Q_{g}. The pressure in storage reservoir 120 increases until a predetermined pressure is reached at which point back-pressure controlled valve 116 begins to allow a flow of gas to bleed from storage reservoir 120 to ozone destructor 140 at a flow rate of Qₜ via supply line 132c. Back-pressure controlled valve 116 allows a desired pressure in storage reservoir 120 to be maintained. Ozone destructor 140 may be exhausted to atmosphere via line 132d.

Although the pressure in storage reservoir 120 has reached equilibrium at this point, the ozone gas concentration in storage reservoir 120 may not yet be at equilibrium output concentration of generator 110. The flow of ozone gas from ozone generator 110 into storage reservoir 120 is continued until the concentration of ozone gas in storage reservoir 120 has substantially reached equilibrium with the ozone concentration of the output of the generator.

Once an equilibrium ozone concentration has been achieved, the flow rate of ozone gas into the storage reservoir is desirably controlled to maintain a constant ozone concentration therein. This may be accompanied by a periodic or continuous bleeding of ozone gas from the storage reservoir. Bleeding ozone gas at a pressure of up to about one pound per square inch (psig) (approximately 6895 Pa) is typically adequate for this purpose. Desirably, for a reservoir having a volume of 56 liters and maintained at a pressure of 2.5 atmospheres, at least 20% of the storage reservoir will be purged and refilled every hour. If a fresh flow of ozone therein is not provided, the stored ozone could degrade prior to use because the half-life of dry, clean ozone gas is on the order of several hours to several days. By maintaining a flow of ozone into the storage reservoir, any ozone gas that has been delivered from storage reservoir 120 to process chamber 130 may also be replenished.

When system 100 is operated in one of the process chamber charging modes, as shown schematically in FIG. 4 and with reference to FIG. 1, valves 162b and 114 are opened and pressurized ozone gas from storage reservoir 120 is allowed to flow into process chamber 130. Valve 114 may be provided directly at the entry port into process chamber 130 or may be provided upstream of process chamber 130 and connected thereto via line 122. When valve 114 is opened, back-pressure controlled valve 116 desirably closes, preventing the flow of ozone to ozone destructor 140. Desirably, the ozone gas will be provided from the storage reservoir to the process chamber at a flow rate of Qᵣ which may be constant or decreasing as the pressure in the storage reservoir drops. By opening valve 122a and closing valve 162a, the flow Q_{g} of ozone gas from ozone generator 110 may be combined with the flow from the storage reservoir to provide ozone to the process chamber at a total flow rate Qₚ given by Qᵣ+Q_{g}. Flow rate Qₚ is in excess of that which could be achieved using the ozone generator alone. Operating the system in such a mode may be particularly useful at times of peak ozone demand in the process chamber.

In another mode, as shown schematically in FIG. 5 and with reference to FIG. 1, both the storage reservoir and the process chamber may be charged simultaneously. Such a mode desirably may be achieved by maintaining optional valve 162b open and closing optional valve 162c. Ozone flows from generator 110 into storage reservoir 120 at a flow rate of Q_{g} and from storage reservoir 120 into process chamber 130 at a flow rate of Qᵣ. Operating in such a mode may be useful when the demand for ozone in the process chamber is less than or equal to the flow rate of ozone from the storage reservoir. Optionally, gas may be bled from storage reservoir 120 to ozone destructor 140 at a flow rate of Qₜ via supply line 132c.

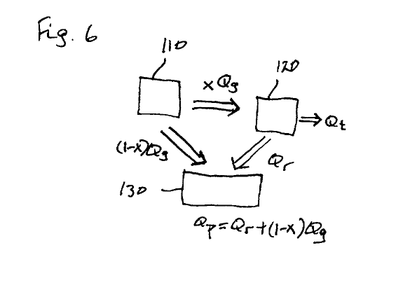

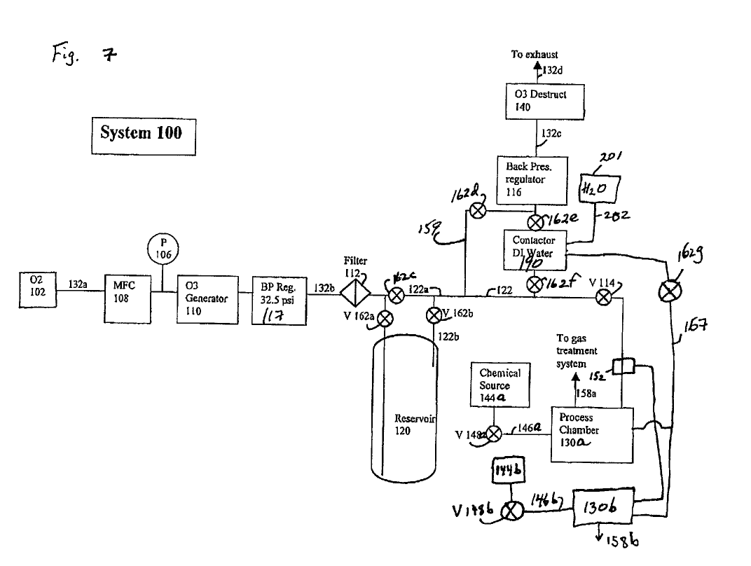

In yet another mode, as shown schematically in FIG. 6 and with reference to FIG. 1, the flow of ozone from the storage reservoir to the process chamber may be supplemented by a portion of the output of the ozone generator. Such a mode desirably may be achieved in an embodiment of the invention in which line 122a is present and optional valve 162b is operated to restrict but not completely eliminate the flow of ozone from the ozone generator to the storage reservoir via line 122b. A portion of the flow of ozone gas from the generator enters storage reservoir 120 and the remainder flows via line 122a to process chamber 130. Where x is the fraction of ozone flow which flows from the generator into the storage reservoir, the total ozone flow Qₚ into the process chamber will be Qᵣ+(1-x)Q_{g}. Operating in such a mode may be useful when the demand for ozone in the process chamber exceeds that which may be suppled form the storage reservoir alone but is less than the flow rate from the ozone generator and the storage reservoir in combination. The fraction x may be as low as 0.1, 0.01 or even 0 and may be as high as 0.9, 0.99 or even 1.0. Optionally, a trickle of gas may be bled from storage reservoir 120 to ozone destructor 140 at a flow rate of Qₜ via supply line 132c.

Thus, in accordance with the invention, ozone may be supplied to the process chamber either exclusively from the storage reservoir or combined with all of the flow from the ozone generator or combined with part of the flow from the ozone generator. In the latter case, the remainder of the ozone flow from the ozone generator may be directed to the storage reservoir where it can be stored and/or discarded.

In a desirable mode of operation of system 100 of FIG. 1, ozone is generated with an ozone generator for a first period of time and delivered to an ozone storage reservoir as illustrated schematically in FIG. 3. Subsequently, ozone is delivered from the ozone storage reservoir to a process chamber with an in-process microelectronic device therein during a second period of time different from the first period of time and the in-process microelectronic device exposed thereto. The ozone may be delivered from the ozone storage reservoir to the process chamber either immediately after a desired amount has been stored or after a gap in time. The time gap is desirably short enough so that the ozone does not unduly degrade. Depending on the length of the time gap, it may be desirable to refresh the ozone storage reservoir preferably by bleeding off ozone from the ozone storage reservoir and adding newly generated ozone to the ozone storage reservoir. Optionally, ozone generated by the generator during the second period of time may also be delivered to the process chamber, as shown schematically in FIG. 4.

The ozone from the ozone storage reservoir may be delivered to the process chamber during the second time period in gaseous form and caused to contact the in-process microelectronic device. The ozone from the storage reservoir may also be dissolved in a liquid such as water using optional contactor 190 and the liquid caused to contact the in-process microelectronic device. In the latter case, the in-process microelectronic device may be immersed in the ozonated liquid or the ozonated liquid may be sprayed on the device.

In another desirable mode of operation, the ozone generation, storage and delivery system disclosed herein may be employed in an inventive method of treating at least one in-process microelectronic device in a process chamber. The treatment method comprises an ozone supply step in which ozone is supplied to a process chamber in the presence of the in-process microelectronic device and a step in which the in-process microelectronic device is processed without delivery of ozone to the process chamber. Using the inventive systems, a quantity of ozone may be generated with the ozone generator during the step in which the in-process microelectronic device is loaded or unloaded or otherwise processed without delivery of ozone to the process chamber. The generated ozone may be stored in a storage, as shown schematically in FIG. 3. Subsequently, ozone may be delivered from the ozone storage reservoir, desirably in combination with ozone from the ozone generator, to the process chamber during the ozone supply step to treat the in-process microelectronic device, as shown schematically in FIG. 4.

The invention is also directed to a method of treating an in-process microelectronic device with ozone where the demand for ozone at the point of use is intermittent. In accordance with the method, Q_{g} liters per minute of ozone are generated during a first time period in which the required flow of ozone into the process chamber Qₚ liter per minute is a fraction (1-x)Q_{g} of the output of the generator where x is between 0 and 1. The excess ozone, namely, xQ_{g} liters per minute of ozone, is stored in the storage reservoir during the first time period, as shown schematically in FIG. 5. Subsequent to storing the ozone, stored ozone is delivered to the process chamber.

Ozone may be generated by flowing oxygen gas from source 102 to ozone gas generator 110. Any commercially available ozone generator may be used. One such suitable ozone generator is a Semozon Model 90.2 ozone generator manufactured by ASTeX (Woburn, Mass.). Desirably, the input pressure of the oxygen gas will be as high as possible to maximize throughput. The Semozon Model 90.2 can handle input pressures up to about 44 psig (303 kPa gauge). Other types of ozone generators including UV based generators may also be used.

Oxygen may suitably be provided to the ozone generator at a pressure ranging from about 0 psi gauge (0 kPa) to about 44 psi gauge (303 kPa). Desirably, oxygen will be provided at a pressure from 34 psi (234 kPa) to 44 psi (303 kPa). More desirably, oxygen will be provided at about 300 kPa gauge as measured by pressure gauge 106. Inside the generator, oxygen gas, O₂, may be dissociated by an electric field. Typically, up to about 20% of the oxygen atoms will combine to form ozone gas, O₃.

The oxygen/ozone gas mixture may then be filtered with filter 112. Examples of filters suitable for use in the inventive system include hydrophobic membrane filters, desirably made of Teflon such as those commercially available form Pall Ultrafine Filtration Corporation, East Hills, N.Y. Metal filters may also be used. Desirably, a 0.003 μm TEFLON™ PFA membrane filter will be used. Filters may optionally be provided elsewhere in the system. For example, a filter may optionally be placed immediately upstream of process chamber 130.

Ozone storage reservoir 120 may be a tank or any other suitable container such as a gas cylinder or a length of pipe, for example, PFA pipe from Entegris, Inc. (Chaska, Minn.) which is closed to prevent leakage of ozone stored therein. Desirably, ozone storage reservoir 120 will be constructed of a material resistant to the deteriorating effects of ozone. Suitable materials for the storage reservoir include stainless steel, quartz or a fluorinated polymer such as Teflon® PFA or Teflon® PTFE commercially available from E.I. DuPont deNemours & Co., Wilmington, Del.

Flow valve 108, valve 114, valve 162 and back-pressure controlled valve 116, as well as any other valves that may be used in the system are desirably made of a material resistant to the deteriorating effects of ozone. Suitable materials include stainless steel, quartz or a fluorinated polymer such as Teflon® PFA or Teflon® PTFE. Desirably, valves 108, 114 and 116 ensure that the flow of ozone through the system proceeds in one direction, i.e. towards process chamber 130. Any type of valve capable of ensuring unidirectional flow may be used. One such suitable valve is a check valve. Unidirectional flow may also be achieved by using a pressurized ozone source. Although the flow of ozone gas is desirably unidirectional, it is within the scope of the invention for the flow to be bidirectional. Bidirectional flow may be desirable in embodiments of the invention having multiple process chambers as disclosed below.

Any of the valves may be manually controlled or provided with controllers. Controllers may include a computing unit having a control program installed therein, with the controller operable to control the controllable valves according to the control program so as to allow for opening and closing of the valves at predetermined times. The valves may be pneumatically controlled or electrically activated.

Delivery lines 122, 122a,b and 132a-d are preferably constructed of a material resistant to the deteriorating effects of ozone. Suitable materials include stainless steel, quartz or a fluorinated polymer such as Teflon® PFA or Teflon® PTFE commercially available from E.I. DuPont deNemours & Co., Wilmington, Del.

Any suitable process chamber may be used in conjunction with the instant invention. In one embodiment of the invention, the process chamber may comprise a spray processor such as the Mercury MP® Spray Processor (FSI International, Inc. Chaska, Minn.). The basic features of the Mercury MP® Spray Processor may be found in U.S. Pat. Nos. 3,990,462 and 6,065,424. Other suitable process chambers include the wet benches common to every semiconductor fabrication plant, the full-flow devices detailed in U.S. Pat. No. 4,984,597 to McConnell, single wafer vapor processing tools which may include liquid rinse capabilities such as the Excalibur™ tool sold by FSI™, Inc., single wafer wet processing tools such as the tool made by SEZ (Villach, Austria) and chemical vapor deposition (CVD) tools such as the tool made by Applied Materials (Santa Clara, Calif.).

The invention also contemplates providing system 100 with a plurality of process chambers that may be served by the same ozone generator(s) and/or reservoir(s). As shown in FIG. 7, two process chambers 130a and 130b are provided. Each of process chambers are shown in communication with an optional additional source of chemicals 144a and 144b with the associated flow valves 148a and 148b, optional controllers (not shown) and supply lines 146a and 146b. Flow to process chambers 130a and 130b is controlled by manifold 152 and valve 114 along with any optional controllers. Additional process chambers may also be provided. Manifold 152 is desirably made of a material resistant to the deteriorating effects of ozone including those disclosed above. Each process chamber may be vented via exhaust line 158a. Additional process chambers may be provided.

Where multiple process chambers are present, the process chambers may simultaneously be supplied with ozone from the storage reservoir and/or ozone generator or may be supplied with ozone at separate times. For example, in one embodiment of the invention, a first process chamber may be supplied with ozone at a time when there is no demand for ozone in a second process chamber and a third process chamber. The second process chamber may be supplied with ozone at a time when no there is no demand for ozone in the first and third process chambers.

The volume of the reservoir depends on factors including the total cycle time, the time period in which Q_{g} demand in the process chamber is reduced or zero, the supply rate of oxygen, the concentration of ozone in the output of the ozone generator, etc. For example, given a 15 minute rinse-dry-reload (RDR) process cycle and an ozone generator 110 supplied with 10 standard liters per minute (slpm) of oxygen and generating 10% ozone by volume (1 slpm of ozone), 150 standard liters of ozone/oxygen mixture may be generated per RDR cycle and stored. Reservoir 120 is initially charged with 150 slpm ozone/oxygen gas mixture. Stored at 35 psig (approximately 241,316 Pa), the ozone would occupy a volume of approximately 45 liters which may be stored in a standard 200 cubic foot gas cylinder. If the generator pressure were increased to 60 psig (approximately 413,685 Pa), the ozone would occupy approximately 30 liters and may be stored in a section of PFA pipe approximately 1.7 meters in length and 150 mm in inner diameter.

In any embodiment, the ozone gas or ozonated liquid may optionally further comprise a scavenger and/or an acid. Suitable scavengers include radical scavengers such as carbonate, bicarbonate, phosphate, carboxylic or phosphonic acids or salts thereof, acetic acid, acetate and combinations thereof or any other scavengers disclosed in U.S. Pat. No. 6,080,531 or EP 0 867 924. Suitable acids include HF, sulfuric acid, hydrochloric acid and nitric acid or any other acid disclosed in WO 99/52654.

The present invention is of particular utility in stripping photoresist and removing other unwanted organic materials from an in-process microelectronic device. Further details of such a process are discussed below and in commonly assigned U.S. Pat. No. 6,080,531.

Where the in-process microelectronic device is subjected to a plurality of treatment cycles, each of which comprises at least one step in which the in-microelectronic device is exposed to ozone and at least one step in which the in-process microelectronic device is not exposed to ozone, for example, a rinse step, ozone may be stored in the ozone storage reservoir during the rinse step(s) and later be delivered to the process chamber from the storage reservoir and desirably the ozone generator in combination during the exposing steps. Where the treatment cycle involves a drying step, a load step and/or an unload step, ozone may be stored during any or all of these steps as well.

The invention is also applicable where a plurality of in-process microelectronic devices are treated in successive batches of one or more wafers. Specifically, in a treatment process in which one or more in-process microelectronic devices are treated in a processor with ozone and subsequently removed from the processor and one or more in-process microelectronic devices subsequently loaded in the processor for treatment, the invention contemplates generating and storing ozone during periods in which the in-process microelectronic devices are removed from the processor and other in-process microelectronic devices loaded in the processor, and using the stored ozone during periods in which ozone is required for treatment of the in-process microelectronic devices.

In one application, ozone from the inventive ozone storage and delivery system is dissolved in a liquid such as water and the resultant ozonated solution sprayed on an in-process microelectronic device or any other substrate as part of a treatment process. The water may optionally comprise one or more scavengers disclosed above and/or one or more acids disclosed above. The in-process microelectronic device or other substrate may be rotated during the process and rinsed following the ozone exposure. Where the device is subjected to multiple such treatment cycles, ozone may be generated and stored during rinse steps and/or during drying steps and/or during loading and/or unloading of the device for use in succession ozone treatment steps. Where successive batches of device are treated, ozone may be generated and stored during the removal of a batch of devices and loading of a batch of devices. Such a treatment process may be used for stripping photoresist or other unwanted organic substances from a device.

The ozone output of the inventive ozone storage and delivery system may also be used in conjunction with an immersion-based process chamber in which a device or substrate is partially or fully immersed in a tank of ozonated liquid or a gaseous based process chamber. The invention further contemplates using the ozone output of the inventive ozone storage and delivery system in conjunction with a gas based system wherein gaseous ozone is flowed into a process chamber optionally along with other gaseous constituents such as gaseous water and/or gaseous acids.

The present invention in some of its embodiments may be better understood by considering the following example.

### EXAMPLE

Oxygen flowed into a Semozon Model 90.2 ozone generator manufactured by ASTeX (Woburn, Mass.). The ozone generator was operated at maximum voltage corresponding to a voltage of 5000-6000 V and produced an ozone/oxygen gas mixture at a flow rate of 10 slpm. The resultant gas mixture was 10% ozone. The gaseous mixture of ozone in oxygen was output from the generator at a pressure of approximately 43 psig (296,475 Pa gauge). In the comparative examples, the ozone/oxygen gas mixture generated by the ozone generator was delivered directly into a Mercury MP® Spray Processor loaded with bare silicon wafers at 10 slpm. In the inventive example, the output of the generator was delivered to an ozone storage reservoir comprising two 8 liter cylinders in parallel. The cylinders were of stainless steel construction with PTFE lining. The ozone storage reservoir was filled to approximately 43 psig (296,475 Pa gauge) over a period of 10-15 minutes. After filling the reservoir, the ozone was delivered to the process chamber from the ozone generator and storage reservoir in combination over a period of approximately two minutes depleting the storage reservoir. The pressure of the ozone gas from the reservoir decreased in time. Ozone from the generator was also delivered to the process chamber. The ratio of stored ozone to freshly generated ozone delivered to the process chamber was approximately 5:1. In all of the experiments, the concentration of the ozone was measured using an ozone detector (model 963) manufactured by BMT (Berlin, Germany) operating at a wavelength of 254 nm.

In comparative experiments 1-3, as summarized below in Table I, the oxygen flow rate into the ozone generator was varied. In the inventive experiment summarized below, oxygen flowed into the ozone generator at a flow rate of 12 slpm. Following delivery of the ozone to the process chamber, the concentration of ozone was measured as a function of time. As shown in FIG. 8, the ozone concentration in the chamber increased most rapidly in the inventive example where ozone was accumulated in a storage reservoir and then released to the process chamber.

| | | | | Concentration |
|---|---|---|---|---|
| | | | Total flow | of ozone |
| | | Avg. flow | rate of | (g/m³) |
| | | rate of | ozone/oxygen | prior to |
| | Flow rate | ozone/ | into | delivery to |
| Experi- | of oxygen | oxygen | chamber | process |
| ment | (slpm)⁺ | (slpm) Qᵣ⁺⁺ | (slpm) Qₚ | chamber* |
| 1 | 46 | 0 | 46 | 69 |
| Comparative | | | | |
| 2 | 27 | 0 | 27 | 102 |
| Comparative | | | | |
| 3 | 12 | 0 | 12 | 170 |
| Comparative | | | | |
| 4 Inventive | 12 | 50 | 62 | 170 |

⁺Flow rate of oxygen (slpm) into the ozone generator
⁺⁺Average flow rate of ozone/oxygen mixture from reservoir (slpm)
*In experiments 1-4, the ozone concentration was measured at the output of the ozone generator.

The above disclosure is intended to be illustrative and not exhaustive. This description will suggest many variations and alternatives to one of ordinary skill in this art. All these alternatives and variations are intended to be included within the scope of the claims where the term “comprising” means “including, but not limited to”. Those familiar with the art may recognize other equivalents to the specific embodiments described herein which equivalents are also intended to be encompassed by the claims.

Further, the particular features presented in the dependent claims can be combined with each other in other manners within the scope of the invention such that the invention should be recognized as also specifically directed to other embodiments having any other possible combination of the features of the dependent claims. For instance, for purposes of claim publication, any dependent claim which follows should be taken as alternatively written in a multiple dependent form from all prior claims which possess all antecedents referenced in such dependent claim if such multiple dependent format is an accepted format within the jurisdiction (e.g. each claim depending directly from claim 1 should be alternatively taken as depending from all previous claims). In jurisdictions where multiple dependent claim formats are restricted, the following dependent claims should each be also taken as alternatively written in each singly dependent claim format which creates a dependency from a prior antecedent-possessing claim other than the specific claim listed in such dependent claim below (e.g. claim 5 may be taken as alternatively dependent from claim 3; claim 6 may be taken as alternatively dependent on claim 3; claim 7 may be taken as alternatively dependent from claims 6, 5 or 3; claim 8 may be taken as alternatively dependent from claims 3-6 etc.).

This completes the description of the preferred and alternate embodiments of the invention. Those skilled in the art may recognize other equivalents to the specific embodiment described herein which equivalents are intended to be encompassed by the claims attached hereto.

1.A method of treating an in-process microelectronic device comprising the steps of:
providing a process chamber with an in-process microelectronic device therein,
providing an ozone generator and an ozone storage reservoir, the ozone storage reservoir in fluid communication with the ozone generator and the process chamber;
generating ozone with the ozone generator for a first period of time and delivering the ozone to the ozone storage reservoir; and subsequently
providing ozone from the ozone storage reservoir to the process chamber during a second period of time different from the first period of time and exposing the in-process microelectronic device thereto.

2.The method of claim 1 wherein the ozone from the ozone storage reservoir is delivered to the process chamber during the second time period in gaseous form and is caused to contact the in-process microelectronic

3. The method of claim 1 wherein the ozone from the ozone storage reservoir delivered to the process chamber during the second time period is dissolved in a liquid.

4.The method of claim 3 wherein the liquid is caused to contact the in-process microelectronic device.

5.The method of claim 4 wherein the in-process microelectronic device is immersed in the liquid.

6.The method of claim 4 wherein the liquid is sprayed onto the in-process microelectronic device.

7.The method of claim 4 wherein the liquid is water.

8.The method of claim 7 wherein the liquid further comprises a scavenger.

9.The method of claim 7 wherein the liquid further comprises an acid.

10.The method of claim 2 wherein an acid is provided to the process chamber along with the gaseous ozone.

11.The method of claim 2 wherein the in-process microelectronic device has photoresist thereon.

12.The method of claim 1 further comprising the step of generating ozone with the ozone generator during the second period of time and delivering the ozone generated during the second period of time to the ozone storage reservoir during the second period of time.

13.The method of claim 1 wherein the second period of time occurs immediately after the first period of time.

14.The method of claim 1 wherein the first and second periods of time are separated in time by a gap.

15.The method of claim 14 wherein the ozone storage reservoir is refreshed by bleeding ozone from the ozone storage reservoir and delivering newly generated ozone to the ozone storage reservoir.

16.The method of claim 1, the in-process microelectronic device subjected to a plurality of treatment cycles, each treatment cycle comprising the steps of exposing the in-process microelectronic device to ozone and rinsing the in-process microelectronic device, wherein ozone is stored in the ozone storage reservoir during the rinsing steps and delivered to the process chamber from the storage reservoir during the exposing steps.

17.ln a method of treating at least one in-process microelectronic device in a process chamber comprising an ozone supply step in which ozone is supplied to the process chamber in the presence of the in-process microelectronic device and a step in which the in-process microelectronic device is processed without delivery of ozone to the process chamber, the improvement comprising the steps of:
providing an ozone generator and an ozone storage reservoir, the ozone storage reservoir in fluid communication with the ozone generator and the process chamber;
generating a quantity of ozone with the ozone generator during the step in which the in-process microelectronic device is processed without delivery of ozone to the process chamber, and delivering the quantity of ozone to the ozone storage reservoir; and subsequently
delivering the ozone from the ozone storage reservoir to the process chamber during the ozone supply step to treat the in-process microelectronic device.

18.A method of treating a substrate with a temporally varying amount of ozone, the substrate comprising an element selected from the group consisting of Si, Ge and Ga, the method comprising the steps of:
providing a process chamber having a substrate therein, the substrate comprising an element selected from the group consisting of Si, Ge and Ga;
providing an ozone generator capable of generating an ozone output of Q_{g} liters per minute;
providing a storage reservoir for storing ozone therein;
generating Q_{g} liters per minute of ozone during a first time period in which a quantity Qₚ less than Q_{g} liters per minute of ozone is required,
storing Q_{g}-Qₚ liters per minute of ozone in the storage reservoir during the first time period; and, subsequent to storing the ozone,
delivering the stored ozone to the process chamber.

19.The method of claim 18 further comprising the steps of generating ozone and delivering the generated ozone to the storage reservoir while the stored ozone is being delivered to the process chamber.

20.The method of claim 18 wherein all of the ozone generated during the first period of time is stored in the storage reservoir.

21.The method of claim 18 further comprising the step of bleeding a portion of the ozone from the storage reservoir and thereafter adding ozone to the storage reservoir.

22.The method of claim 18 wherein the substrate comprises Si, Ge, GaAs or SiO₂.

23.A processor for treating an in-process microelectronic device comprising:
an ozone generator having a first output of ozone;
an ozone storage reservoir comprising ozone therein,
a process chamber for holding the in-process microelectronic device;
a first line connecting the ozone generator and the storage reservoir, and a second line connecting the storage reservoir to the process chamber, the second line including a controllable valve controlling flow of ozone between the storage reservoir and the process chamber whereby quantities of ozone may be delivered from the storage reservoir to the process chamber at selected times; and
a controller in communication with the controllable valve, the controller including a computing unit having a control program installed therein, the controller operable to control the controllable valve according to the control program so as to allow for storage of ozone in the storage reservoir at predetermined time and to provide ozone to the process chamber from the storage reservoir at predetermined times.

24.The processor of claim 23 wherein the controller is in mechanical communication with the first and second controllable valves.

25.The processor of claim 23 wherein the controller is in mechanical communication with the first and second controllable valves.

26.A method of treating an in-process microelectronic device comprising the steps of:
a) providing a first flow of gas comprising ozone;
b) storing at least a portion of the first flow in a gaseous state in a storage reservoir;
c) withdrawing a second flow of gas from the reservoir;
d) combining the second flow and at least a portion of the first flow to provide a combined gas flow;
e) incorporating the combined gas flow into a treatment of the in-process microelectronic device.

27.The method of claim 26 wherein the entirety of the first flow is stored in the storage reservoir during the storing step.

28.The method of claim 26 wherein the entirety of the first flow is combined with the second flow during the combining step.

29.The method of claim 26 wherein at least a second portion of the first flow is stored in the storage reservoir during the combining step.

30.A method of using a supply of ozone gas to carry out a process having a temporally variable demand for ozone comprising:
a) providing a steady state supply of a gas comprising ozone;
b) during a period of a relatively low demand for ozone by the process, storing an amount of ozone gas;
c) during a period of a relatively high demand for ozone by the process, carrying out the process using the stored ozone and at least a portion of the steady state supply of ozone.

31.The method of claim 30 wherein the entirety of the steady state supply of ozone is used in step c) to carry out the process.

32.The method of claim 30 wherein a second portion of the steady state supply of ozone is stored during step b).
